(19) United States
(12) Patent Application Publication
(10) Pub. No.: US 2013/0313525 A1
(43) Pub. Date: Nov. 28, 2013

(54) Nanowire-based Transistor, Method for Fabricating the Transistor, Semiconductor Component Incorporating the Transistor, Computer Program and Storage Medium Associated with the Fabrication Method

(71) Applicants: Commissariat a L'energie Atomique et aux Energies Alternatives, Paris (FR); Universite Joseph Fourier - Grenoble, Grenoble (FR); CNRS, Paris (FR)

(72) Inventors: Guillaume Rosaz, Les Marches (FR); Pascal Gentile, Voiron (FR); Thierry Baron, Romans (FR); Bassem Salem, Fontaine (FR); Nicolas Pauc, Sassenage (FR)

(21) Appl. No.: 13/902,223

(22) Filed: May 24, 2013

(30) Foreign Application Priority Data
May 25, 2012 (FR) 12/54822

(51) Int. Cl. H01L 29/775; H01L 29/66

(52) U.S. Cl. CPC H01L 29/775; H01L 29/66439
USPC 257/29; 438/268

(57) ABSTRACT

The transistor (100) comprises a nanowire (101) at least partially forming a channel of the transistor (100), a source contact (102) arranged at a first longitudinal end (103) of the nanowire (101), a drain contact (104) arranged at a second longitudinal end (105) of the nanowire (101), and a gate (106) arranged on the nanowire (101) between the source contact (102) and the drain contact (104). Furthermore, a portion of the gate (106) covers, with the interposition of a dielectric material (107), a corresponding portion of the source contact (102) and/or of the drain contact (104) arranged along the nanowire (101) between its two longitudinal ends (103, 105).

### FIELD OF THE INVENTION

The invention relates to the field of the transistors applied to nanotechnologies such as, for example, field effect transistors (FET).

The subject of the invention is more particularly a nanowire-based transistor.

### STATE OF THE ART

Document WO2006/135336 describes, as illustrated in FIG. 1, a transistor formed on a substrate 1. A nanowire 2 rises up from the substrate 1 with the interposition of a source contact 3. The end of the nanowire 2 opposite to the substrate 1 is covered by a drain contact 4. A gate 5 of the transistor is interposed between the source contact 3 and the drain contact 4, and surrounds a portion of the nanowire 2.

Such a transistor is not totally satisfactory because it has a high access resistance.

There is therefore the problem of improving the transistor as described previously.

### OBJECT OF THE INVENTION

The purpose of the present invention is to propose a solution that makes it possible to reduce the access resistance of the transistor.

This aim is addressed in that the transistor comprises a nanowire at least partially forming a channel of the transistor, a source contact arranged at a first longitudinal end of the nanowire, a drain contact arranged at a second longitudinal end of the nanowire, and a gate arranged on the nanowire between the source contact and the drain contact, a portion of the gate covering, with the interposition of a dielectric material, a corresponding portion of the source contact and/or of the drain contact arranged along the nanowire between its two longitudinal ends.

Advantageously, the corresponding portion of the source contact and/or of the drain contact, arranged along the nanowire between its two longitudinal ends, is distinct from the nanowire and covers a part of the outer surface of the nanowire.

According to one implementation, the nanowire comprises three sections staged along its length between its two longitudinal ends, a first section being coated by the source contact, a second section being coated by the drain contact, and a third section being coated at least partially by the gate with the interposition of the dielectric material.

Advantageously, the gate also at least partially coats, with the interposition of the dielectric material, the source contact, and/or the drain contact.

Preferably, the length of the gate portion covering, with the interposition of the dielectric material, the corresponding portion of the source contact and/or of the drain contact is between 5% and 90% of the length of said contact, and more particularly between 30% and 70%, said gate and contact portions being oriented along the length of the nanowire.

Preferably, the source and drain contacts each form a sheath respectively surrounding the first and second sections of the nanowire, and the gate totally surrounds at least a part of the third section of the nanowire, and totally surrounds at least a portion of the source contact and/or of the drain contact with the interposition of the dielectric material.

The invention also relates to a semiconductor component comprising at least one transistor.

The invention also relates to a method for fabricating a transistor comprising the following phase:
forming a nanowire intended to serve at least partially as channel of the transistor,
simultaneously forming a source contact at a first longitudinal end of the nanowire, and a drain contact at a second longitudinal end of the nanowire opposite to the first longitudinal end,
forming a gate so that a portion of the gate covers, with the interposition of a dielectric material, a corresponding portion of the source and/or drain contact arranged along the nanowire between its two longitudinal ends.

According to one implementation, the phase of forming the source contact and the drain contact comprises the following steps:
covering the outer surface of the nanowire, at least along its length, with a material intended to form the source contact and the drain contact,
etching said material intended to form the source contact and the drain contact between the two longitudinal ends of the nanowire so as to delimit the source contact and the drain contact.

According to one implementation, before etching the material intended to form the source contact and the drain contact, the phase of forming the source contact and the drain contact comprises a step of delimiting the area to be etched by forming two etching masks:
a first etching mask being formed on a part of the material intended to form the source contact and the drain contact at a base of the nanowire situated at an interface between one of the longitudinal ends of the nanowire and a substrate from which the nanowire rises, and
a second etching mask being formed on a part of the material intended to form the source contact and the drain contact at the longitudinal end of the nanowire opposite to the substrate.

Preferably, the second etching mask is formed on a sacrificial layer deposited, prior to the forming of the second etching mask, on the first etching mask, and before performing the step of etching the material intended to form the source contact and the drain contact, this sacrificial layer is removed.

According to one implementation, the method comprises forming a plurality of transistors, each formed from one or more associated nanowires, and the second etching mask is formed by the deposition of a layer forming, after removal of the sacrificial layer, a suspended membrane linking a plurality of nanowires at their longitudinal ends opposite to the substrate with the interposition of a part of the material intended to form the source contact and the drain contact.

Advantageously, the phase of forming the gate comprises:
the deposition of a gate oxide, also forming the dielectric material, so as to cover at least the source contact, the drain contact and the part of nanowire situated between the source contact and the drain contact,
the deposition, on the gate oxide, of a material intended to form the gate,
the structuring of the material deposited on the gate oxide to form the gate.

Advantageously, the structuring comprises the removal of a part of the material intended to form the gate covering the gate oxide at the longitudinal end of the nanowire opposite to the substrate, and of another part of the material intended to form the gate covering the gate oxide at the base of the nanowire.

The method may also comprise a phase of forming gate, source and drain interconnections, the source and drain interconnections being formed by removal of a part of the gate oxide in areas where the gate material has been removed during the structuring of the gate.

The invention also relates to a data storage medium to be read by a calculator, on which is stored a computer program comprising computer program code means for implementing the phases and/or steps of a fabrication method as described.

The invention also relates to a computer program comprising a computer program code means suitable for carrying out the phases and/or steps of a fabrication method as described when the program is executed by a calculator.

### BRIEF DESCRIPTION OF THE DRAWINGS

Other advantages and features will emerge more clearly from the following description of embodiments of the invention given as non-limiting examples and represented in the appended drawings, in which:

FIG. 1 illustrates a cross-sectional view of a transistor according to the prior art,

FIG. 2 illustrates a cross-sectional view of a transistor according to an embodiment of the present invention,

FIG. 3 schematically represents a method for fabricating a transistor according to FIG. 2,

FIGS. 4 to 18 represent cross-sectional views of a transistor during production at different steps of the fabrication method.

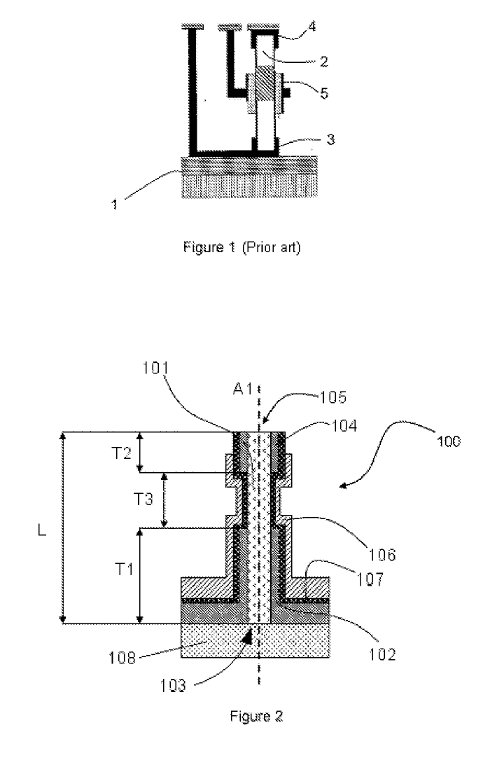

### DESCRIPTION OF PREFERRED EMBODIMENTS OF THE INVENTION

The transistor described hereinbelow differs from that of the prior art in particular in that a gate of said transistor comprises a part situated facing a portion of a source contact of the transistor and/or a portion of a drain contact of the transistor situated along the nanowire between its two longitudinal ends.

In FIG. 2, the transistor 100 comprises a nanowire 101 at least partially forming a channel of the transistor 100. A source contact 102 of the transistor 100 is arranged at a first longitudinal end 103 of the nanowire 101, and a drain contact 104 of the transistor 100 is arranged at a second longitudinal end 105 of the nanowire 101. A gate 106 is arranged on the nanowire between the source contact 102 and the drain contact 104, so that a portion of the gate 106 covers, with the interposition of a dielectric material 107, a corresponding portion of the source contact 102 and/or of the drain contact 104 arranged along the nanowire 101 between its two longitudinal ends 103 and 105.

The expression “source contact and/or drain contact” should be understood to mean contacts configured so as to inject and/or extract charges into and from the transistor. In practice, these source and/or drain contacts form, with the channel, areas of overlap where the charges can be injected into the channel and/or extracted from the channel. These areas of overlap then form the source and the drain of the transistor. In other words, the source and drain contacts are here preferably distinct from the associated nanowire.

The overlap makes it possible to limit the access resistance, and the embodiment in which the source contact and the drain contact each have a portion covered by the gate with the interposition of the dielectric material 107 along the nanowire, is preferred in as much as it minimizes this access resistance.

In the particular example of FIG. 2, the source contact 102 and the drain contact 104 are distinct from the nanowire 101 and each partially covers the nanowire 100. In other words, the corresponding portion of the source contact 102 and/or of the drain contact 104, arranged along the nanowire 101 between its two longitudinal ends and covered by the gate 106 with the interposition of the dielectric material 107, covers part of the outer surface of the nanowire 101, and is distinct from the nanowire 101.

Typically, the dielectric material 107 is also called gate oxide.

In FIG. 2, the nanowire 100 notably comprises three sections T1, T2, T3 staged along its length L between its two longitudinal ends 103 and 105. A first section T1 is coated by the source contact 102, a second section T2 is coated by the drain contact 104, and a third section T3 is at least partially coated by the gate 106 with the interposition of the dielectric material 107. In fact, it can be considered that at least the section T3 of the nanowire corresponds to the channel of the transistor 100 with which the gate 106 is associated. Moreover, the gate 106 also coats, at least partially, with the interposition of the dielectric material 107, the source contact 102, preferably at the interface between the first and third sections T1, T3, and/or the drain contact 104, preferably at the interface between the second and third sections T2, T3.

The term “Coating” should be understood to mean providing 360 degree coverage around the longitudinal axis A1 of the nanowire 101. In other words, the source contact 102 and the drain contact 104 each form a sheath respectively surrounding the first and second sections T1, T2 of the nanowire 101 in particular around the axis A1, and are advantageously in direct contact with the outer surface of the nanowire 101. The gate 106 totally surrounds at least a part of the third section T3 of the nanowire 101, and totally surrounds at least a portion of the source contact 102 and/or of the drain contact 104 with the interposition of the dielectric material 107. Thus, the dielectric material can be in direct contact with the nanowire 101 at the third section T3, and in direct contact with a portion of the source contact 102 and/or of the drain contact 104. The gate 106 is then in direct contact with the dielectric material 107 in particular so as to ensure a field effect between the source contact 102 and the drain contact 104.

Moreover, the nanowire 101 rises up from one of its longitudinal ends from a substrate 108. The nanowire 101 can therefore be in direct contact with the substrate 108. In FIG. 2, the end situated at the substrate 108 is the end 103 associated with the source contact 102, but this scheme could be reversed so that it is the end 105 and the drain contact 104 which are situated at the substrate 108.

The expression “length of” the nanowire 101, should be understood to mean the distance separating its two longitudinal ends 103 and 105, in particular represented by the reference L in FIG. 2. The length of the sections is defined parallel to the dimension defining the length of the nanowire 101 between its two longitudinal ends.

Advantageously, the length of the gate portion covering, with the interposition of the dielectric material 107, the corresponding portion of the source contact and/or of the drain contact is between 5% and 90% of the length of the contact, and more particularly between 30% and 70%. The gate and contact portion lengths are oriented along the length of the nanowire.

A semiconductor component may comprise at least one transistor as described hereinabove, or obtained according to the method described below.

The description hereinbelow notably relates to a method for fabricating at least one transistor as described above. Such a method is illustrated in FIGS. 2 to 18. In FIGS. 4 to 18, two nanowires are represented each time so as to form two transistors. However, the method is not limited to two transistors. In fact, there can be a single nanowire intended to form a single transistor, or at least two nanowires each intended to form a transistor.

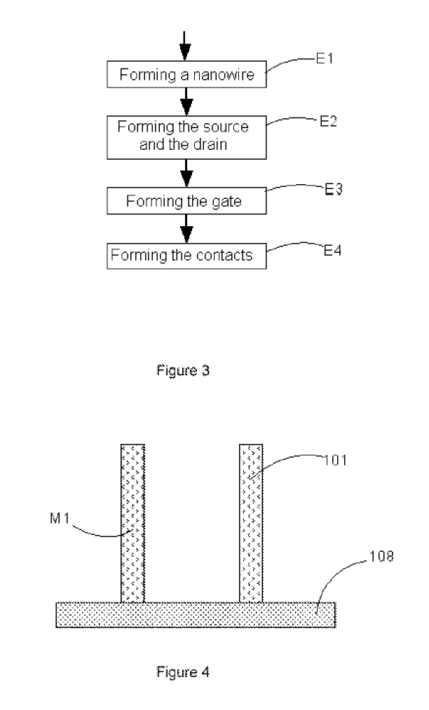

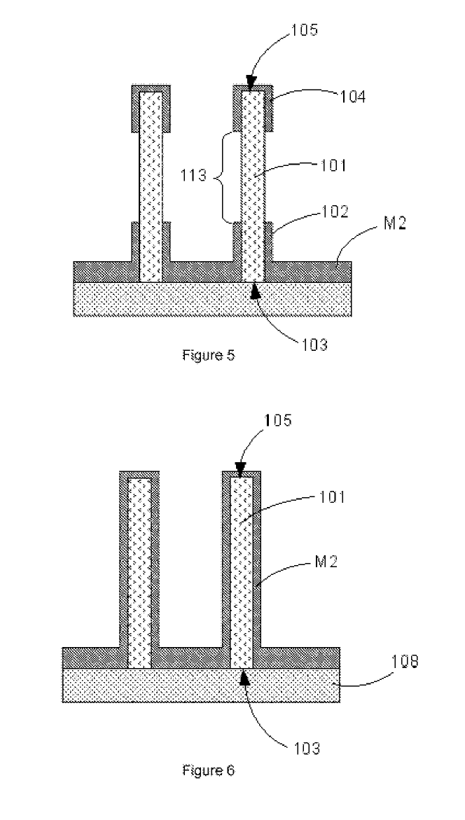

Generally, the method for fabricating at least one transistor as illustrated in FIG. 3 comprises a phase E1 in which a nanowire 101 is formed (FIG. 4) intended to serve at least partially as channel of the transistor, then, simultaneously, a source contact 102 is formed E2 at a first longitudinal end 103 of the nanowire 101, and a drain contact 104 is formed at a second longitudinal end 105 of the nanowire 101 opposite to the first longitudinal end 103 (FIG. 5). Finally, a gate 106 is formed E3 so that a portion of the gate 106 covers, with the interposition of a dielectric material 107, a corresponding portion of the source contact 102 and/or of the drain contact 104, said corresponding portion being arranged along the nanowire between its two longitudinal ends 103, 105 (FIG. 2). The gate 106, the source contact 102 and the drain contact 104 form the transistor whose channel is at least partially delimited by the nanowire 101.

FIG. 4 illustrates a particular embodiment of the phase in which the nanowire 101 is formed. Each nanowire 1 is in fact a vertical structure rising up, for example, from a substrate 108. This vertical structure based on semiconductor materials can be obtained by growth or by etching IV-IV materials (for example Si, SiGe, Ge, etc.) or III-V materials (InAs, InP, GaAs, etc.) or II-VI materials (ZnO, etc.). The substrate 108 may be a monocrystal, a polycrystal, metal, or an amorphous material. The material of the vertical structure is designated M1.

Advantageously, the phase of formation of the source contact and of the drain contact comprises a step of covering the outer surface of the nanowire 101, at least along its length, with a material M2 intended to form the source contact 102 and the drain contact 104 (FIG. 6). In fact, the covering step can be performed by deposition of a source contact or drain contact metal, for example according to a method chosen from cathodic sputtering, CVD deposition (chemical vapour phase deposition), a PECVD deposition (plasma-enhanced chemical vapour phase deposition), an ALD deposition (atomic layer deposition), a deposition by magnetron sputtering, or even an MOCVD deposition (chemical vapour deposition using metal organic precursors) or PE-MOCVD deposition (plasma-enhanced chemical vapour deposition using metal organic precursors). The material forming the source contact or the drain contact is denoted M2, it can be deposited as in the FIG. 6 by conformal deposition. The material M2 can be a metal (for example Pt, Ni, Co, Pd, Ti, Al, etc) or a degenerate semiconductor such as p- or n-doped polysilicon (respectively 10¹⁹ atoms/cm³ of boron or of phosphorus for example).

In FIG. 6, the material M2 totally covers the nanowire and at least one part of the substrate 108 at the interface with the nanowire. Preferably, the substrate 108 is entirely covered by the material M2 on the face of the substrate 108 bearing the nanowire or nanowires 101.

Advantageously, in order to control the implementation of the method, the material M2 can be etched selectively relative to the material M1.

Furthermore, the phase of formation of the source contact and of the drain contact also comprises a step of etching said material M2 intended to form the source contact 102 and the drain contact 104 between the two longitudinal ends 103, 105 of the nanowire 101 so as to delimit the source contact 102 and the drain contact 104 as illustrated in FIG. 5.

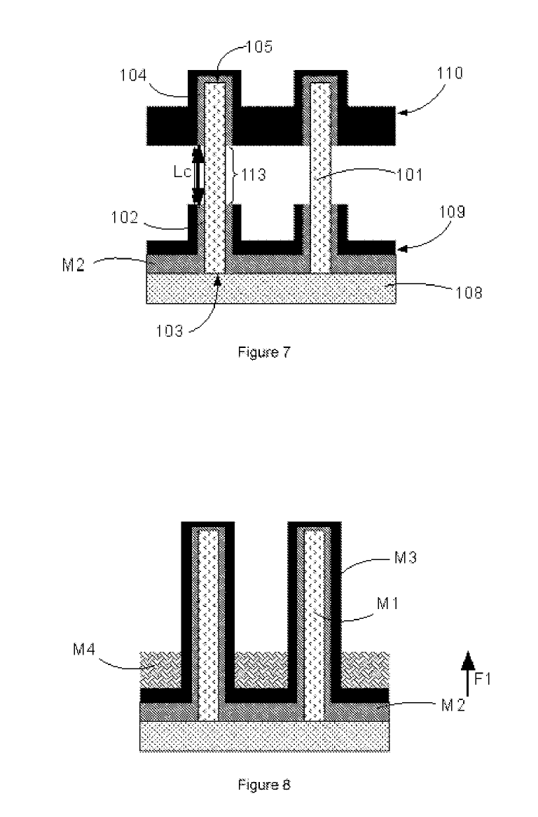

According to a particular implementation, before etching the material M2 intended to form the source contact and the drain contact, the phase of formation E2 of the source contact and of the drain contact comprises a step of delimiting the area to be etched 113 (FIG. 5) by the formation of two etching masks. In FIG. 7, a first etching mask 109 is formed on part of the material M2 intended to form the source contact 102 and the drain contact 104 at a base of the nanowire 101 situated at an interface between one of the longitudinal ends 103 of the nanowire 101 and the substrate 108 from which the nanowire 101 rises up. A second etching mask 110 is formed on a part of the material M2 intended to form the source contact 102 and the drain contact 104 at the longitudinal end 105 of the nanowire 101 opposite to the substrate 108. Then, between the two etching masks 109 and 110, the material M2 can be removed by selective etching over a length Lc associated with the area 113 to be etched. In other words, the material M2 can be etched selectively relative to the materials used to form the etching masks 109 and 110, so as to locally remove the material M2 up to the outer surface of the nanowire 101 between the first etching mask and the second etching mask 109, 110.

The first etching mask 109 can be produced as illustrated in FIGS. 8 and 9. Firstly, a material M3 is deposited by conformal (isotropic) method, for example by cathodic sputtering, by magnetron sputtering, or even according to ALD, CVD, PECVD, MOCVD, or PE-MOCVD. The material M3 (FIG. 8) intended to form the first mask 109 (FIG. 7) is chosen such that the material M2 can be etched selectively relative to the material M3 and vice versa. Moreover, M3 is also chosen so as to be etched selectively relative to M1. The conformal deposition covers, advantageously totally, the layer of material M2. After conformal deposition of the material M3, the height H1 (FIG. 9) of the future source contact in the direction F1 is defined by the deposition of a sacrificial mask of material M4 (FIG. 8). This material M4 can be etched selectively relative to M3 and vice versa. Thus, to move from FIG. 8 to FIG. 9, the material M3 is first etched without prejudice to the material M2, for example by wet or dry etching, as far as the sacrificial mask of material M4, then the material M4 is next removed so as to obtain the first mask 109 of FIG. 9.

According to one alternative, the material M3 is not deposited by conformal deposition but rather by non-conformal (anisotropic) method, for example HDP-CVD (high density plasma chemical vapour deposition). This makes it possible to limit the steps of the method, without having to use a sacrificial mask as in the case of the conformal deposition. The height H1 is then directly adjusted during the deposition of the material M3 to form the first mask 109.

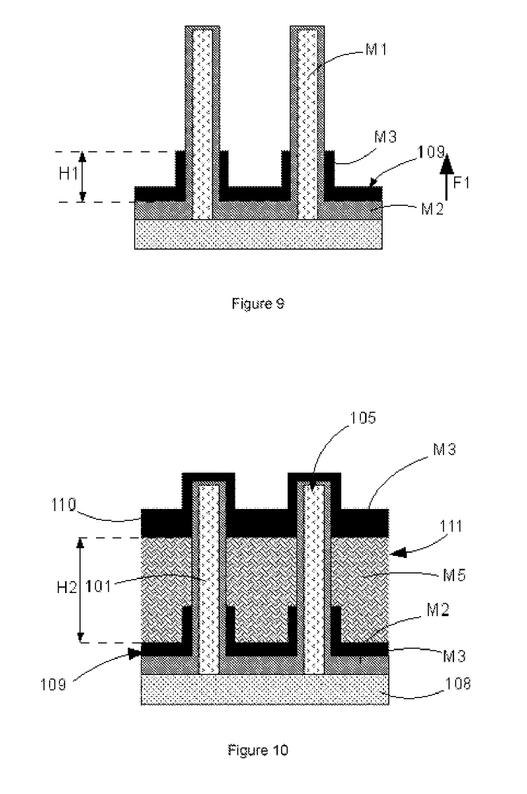

The second etching mask 110 of FIG. 7 can be formed as illustrated in FIG. 10 on a sacrificial layer 111 deposited, prior to the formation of said second etching mask 110, on the first etching mask 109. Before carrying out the step of etching the material M2 intended to form the source contact and the drain contact, this sacrificial layer 111 is removed so as to leave the material M2 free over the desired length Lc of the channel (FIG. 7).

In other words, starting from FIG. 9, it is possible to produce the second mask 110 by depositing the sacrificial layer 111 of material M5 (FIG. 10). Typically, this material M5 can be a resin, an HDP-CVD oxide, an HDP-CVD nitride, or even methylsiloxane. The thickness H2 of this layer 111, relative to the substrate 108 will subsequently determine the distance Lc between the source and drain contacts of the future transistor. The thickness H2 of this layer 111 can be thinned by dry etching in order to obtain a smaller distance between the source contact and the drain contact. The material M5 can be etched selectively relative to M2 and M3. Then (FIG. 10), on this sacrificial layer 111, the second mask 110 is deposited in a conformal or non-conformal manner. In practice, it will only be necessary to ensure that the deposited thickness is sufficient to protect the outer surface of the material M2 in an area surrounding the body of the nanowire along its length at the end 105 of the nanowire 101 opposite to the substrate 108 in the example. The material of the second mask 110 is advantageously of the type M3, that is to say the same as that used for the first mask 109. M3 can be etched selectively relative to M5.

Advantageously, the method comprises the formation of a plurality of transistors, each formed from one (or more) associated nanowires 101. The second etching mask 110 is formed by the deposition of a layer forming, after removal of the sacrificial layer 111 (FIG. 10), a suspended membrane (FIG. 7) linking a plurality of nanowires at their longitudinal ends opposite to the substrate 108 with the interposition of a part of the material M2 intended to form the source contact and the drain contact.

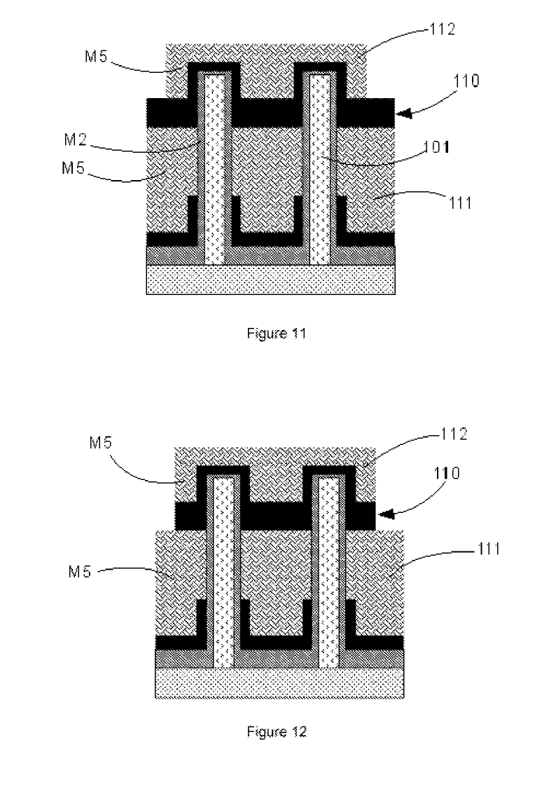

In fact, in the context of the formation of a suspended membrane, the latter can be delimited before the removal of the sacrificial layer 111 of material M5 of FIG. 10. FIGS. 11 and 12 illustrate such a delimiting. Advantageously, the delimitating makes it possible to reduce the size of the membrane to a surface configured to simply include and coat all the ends of all the nanowires 101 opposite to the substrate 108 with the interposition of the material M2. This limiting of the size of the membrane makes it possible to avoid breaking the nanowires between the two etching masks 109, 110 once the sacrificial layer 111 is removed. In FIG. 11, a photosensitive resin 112 (which could also be replaced by an electrosensitive resin) is deposited, then the deposition of the resin 112 is followed by lithography. This resin serves as a mask to the etching of a part of the second mask 110 to delimit the membrane. The material used as photosensitive resin is advantageously of type M5. Then, each part of the second mask 110 left free is etched (FIG. 12). After the delimiting of the membrane, the photosensitive resin 112 and the sacrificial layer 111 are both etched before etching M2 in order to obtain the result of FIG. 7. The advantage of using the material M5 as sacrificial layer 111 and photosensitive resin 112 is that a single etching step, by chemical or physical means, is sufficient to remove them both.

Generally, once the first mask 109 and the second mask 110 are delimited, the material M2 is etched between these two masks 109 and 110, for example by wet or dry means, so as to delimit the source contact 102 and the drain contact 105 on each nanowire (FIG. 7).

Once the source contact 102 and the drain contact 104 are delimited, the first mask 109 and the second mask 110 of FIG. 7 can be removed so as to obtain at least an assembly of the type of FIG. 5 comprising at least one nanowire.

Starting from the case where the source contact 102 and the drain contact 104 are delimited for each nanowire (FIG. 5), it is possible to produce the gate 106 as described previously so as to obtain the result of FIG. 2.

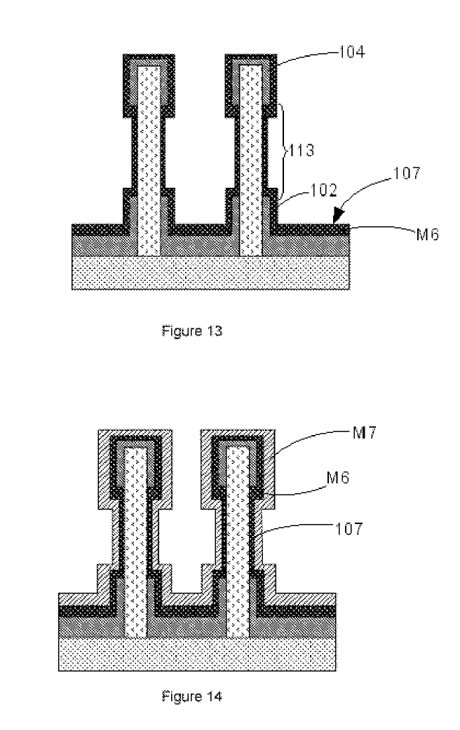

According to a particular implementation, the phase of formation of the gate can comprise a step of deposition (FIG. 13) of a gate oxide 107, also forming the dielectric material M6, so as to cover at least the source contact 102, the drain contact 104 and the part 113 of the nanowire 101, situated between the source contact 102 and the drain contact 104. This part 113 may, optionally, have been freed by the step of etching the material M2 intended to form the source contact 102 and the drain contact 104. Then, the phase of formation of the gate 106 can comprise a step of deposition (FIG. 14), on the gate oxide 107, of a material M7 intended to form the gate, and finally a step of structuring the material M7 deposited on the gate oxide to form the gate.

In fact, in FIG. 13, the material M6 is deposited in a conformal manner so as to cover the source contact 102, the drain contact 104, the nanowire between the source and drain contacts, and advantageously the space between the nanowires when there are two or more thereof. In FIG. 14, the material M7 is deposited by conformal deposition so as to cover the material M6, preferably all of it. The material M7 can be etched selectively relative to the material M6. As illustrated in FIG. 15, the gate 106 can then be delimited by a deposition of an etching mask 114 for the gate, then by etching (for example by dry or wet means) a part of the material M7 not protected by the gate etching mask 114, and this can be done as far as the material M6. The etching mask 114 can be a resin deposited by turning, or an oxide or a nitride. The height H3 of the layer forming the gate etching mask 114 can be lowered using a dry etching so as to accurately calculate the possible coverage Z1 between the gate 106 and the drain contact 104. The material used to form the gate etching mask 114 is designated by M8. The material M7 can be etched selectively relative to the material M8.

In other words, the structuring may comprise the removal of a part of the material M7 intended to form the gate 106 covering the gate oxide 107 at the longitudinal end 105 of the nanowire 101 opposite to the substrate 108. This removal of the material M7 is carried out, for each nanowire, in an area Z2. Moreover, another part of the material M7, intended to form the gate, covering the gate oxide at the base of the nanowire (that is to say on the substrate 108) is also removed, so as to facilitate access to the source contact 102 on the substrate 108 to form a contact start point, also called source interconnection. In FIG. 15, this removal of the material M7 on the substrate is carried out in an area Z3.

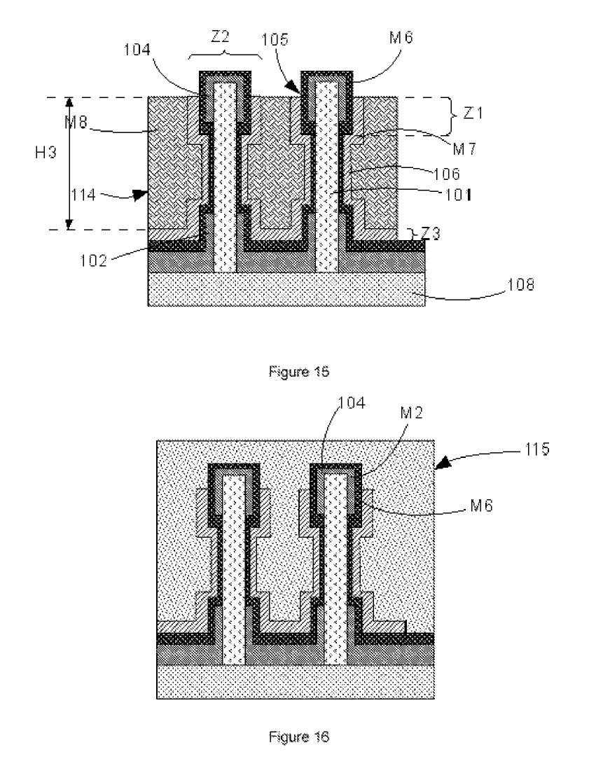

Then, if the material M8 is a resin, it is removed selectively by dry or wet etching. Then, each future transistor is coated by an insulator 115 (FIG. 16) for example by PE-CVD or CVD or LPCVD deposition or cathodic sputtering or magnetron sputtering. In the case where the material M8 is an insulator, it can be retained and participate in the coating with another material deposited thereafter.

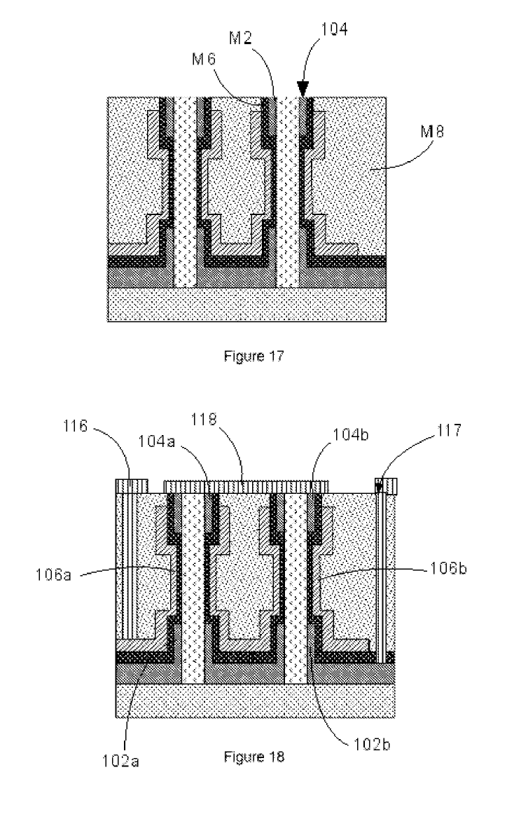

The coating-forming material M8 is then lowered by an etching suitable for etching said coating material, the material M2 and the material M6 so as to allow free access to the drain contact 104 (FIG. 17).

The contact start points or source interconnections, of the drain and of the gate can be produced. Thus, the method may comprise a phase of forming gate 116, source 117 and drain 118 interconnections (FIG. 18) the source and drain interconnections being formed by the removal of part of the gate oxide in the areas Z2 and Z3 where the gate material was removed during the structuring of the gate. After having removed the gate oxide, the interconnections 116, 117, 118 can be deposited and formed as illustrated in FIG. 18.

The source, drain and gate interconnections should be understood to be the electrical links linking the source contact, the drain contact and the gate to a circuit. The circuit then comprises other elements linked electrically to the transistor via these interconnections.

Advantageously, at the end of the method an electronic component is obtained that comprises a plurality of nanowires of which, as in FIG. 18, all the source contacts 102a, 102b are electrically linked together, all the drain contacts 104a, 104b are electrically linked together, and of which all the gates 106a, 106b are electrically linked together.

A data storage medium that can be read by a calculator, on which is stored a computer program, may comprise computer program code means for implementing the phases and/or the steps of the method as described above.

A computer program may comprise a computer program code means suitable for carrying out the phases and/or the steps of the method described above, when the program is executed by a calculator.

As indicated previously for the transistor, in the method, the source contact and the drain contact can be reversed.

The result of the above is that the use of two hard masks, one of which is advantageously in the form of a membrane suspended above the other by nanowires, makes it possible to define and control the length Lc of the channel of a vertical transistor by virtue of a direct control of the spacing between the drain and source contacts.

In addition, producing a coating gate having an opposite along the nanowire with the source contact and/or the drain contact while adjusting the surface area of the opposite allows for better electrostatic control of the channel and lower operating voltages.

Furthermore, the method described here makes it possible to control the dimensioning of the channel, that is to say the position of the source and drain contacts on a nanowire.

1. Transistor comprising a nanowire at least partially forming a channel of the transistor, a source contact arranged at a first longitudinal end of the nanowire, a drain contact arranged at a second longitudinal end of the nanowire, and a gate arranged on the nanowire between the source contact and the drain contact, wherein a portion of the gate covers, with interposition of a dielectric material, a corresponding portion of the source contact and/or of the drain contact arranged along the nanowire between its two longitudinal ends.

2. Transistor according to claim 1, wherein the corresponding portion of the source contact and/or of the drain contact, arranged along the nanowire between its two longitudinal ends, is distinct from the nanowire and covers a part of the outer surface of the nanowire.

3. Transistor according to claim 1, wherein the nanowire comprises three sections staged along its length between its two longitudinal ends, a first section being coated by the source contact, a second section being coated by the drain contact, and a third section being coated at least partially by the gate with interposition of the dielectric material.

4. Transistor according to claim 3, wherein the gate also at least partially coats, with interposition of the dielectric material, the source contact, and/or the drain contact.

5. Transistor according claim 1, wherein the length of the gate portion covering, with the interposition of the dielectric material, the corresponding portion of the source contact and/or of the drain contact is between 5% and 90% of the length of said contact, and more particularly between 30% and 70%, said gate and contact portion lengths being oriented along the length of the nanowire.

6. Transistor according to claim 3, wherein the source and drain contacts each form a sheath respectively surrounding the first and second sections of the nanowire, and in that the gate totally surrounds at least a part of the third section of the nanowire, and totally surrounds at least a portion of the source contact and/or of the drain contact with the interposition of the dielectric material.

7. Semiconductor component which comprises at least one transistor according to claim 1.

8. Method for fabricating a transistor comprising the following phase:
forming a nanowire intended to serve at least partially as channel of the transistor,
wherein it comprises the following phases:
simultaneously forming a source contact at a first longitudinal end of the nanowire, and a drain contact at a second longitudinal end of the nanowire opposite to the first longitudinal end,
forming a gate so that a portion of the gate covers, with the interposition of a dielectric material, a corresponding portion of the source and/or drain contact arranged along the nanowire between its two longitudinal ends.

9. Method for fabricating a transistor according to claim 8, wherein the phase of forming the source contact and the drain contact comprises the following steps:
covering the outer surface of the nanowire, at least along its length, with a material intended to form the source contact and the drain contact,
etching said material intended to form the source contact and the drain contact between the two longitudinal ends of the nanowire so as to delimit the source contact and the drain contact.

10. Method for fabricating a transistor according to claim 9, wherein, before etching the material intended to form the source contact and the drain contact, the phase of forming the source contact and the drain contact comprises a step of delimiting the area to be etched by forming two etching masks:
a first etching mask being formed on a part of the material intended to form the source contact and the drain contact at a base of the nanowire situated at an interface between one of the longitudinal ends of the nanowire and a substrate from which the nanowire rises, and
a second etching mask being formed on a part of the material intended to form the source contact and the drain contact at the longitudinal end of the nanowire opposite to the substrate.

11. Method for fabricating a transistor according to claim 10, wherein the second etching mask is formed on a sacrificial layer deposited, prior to the forming of the second etching mask, on the first etching mask, and in that, before performing the step of etching the material intended to form the source contact and the drain contact, this sacrificial layer is removed.

12. Method for fabricating a transistor according to claim 11, wherein it comprises forming a plurality of transistors, each formed from one or more associated nanowires, and in that the second etching mask is formed by the deposition of a layer forming, after removal of the sacrificial layer, a suspended membrane linking a plurality of nanowires at their longitudinal ends opposite to the substrate with the interposition of a part of the material intended to form the source contact and the drain contact.

13. Method for fabricating a transistor according to claim 8, wherein the phase of forming the gate comprises:
the deposition of a gate oxide, also forming the dielectric material, so as to cover at least the source contact, the drain contact and the part of nanowire situated between the source contact and the drain contact,
the deposition, on the gate oxide, of a material intended to form the gate,
the structuring of the material deposited on the gate oxide to form the gate.

14. Method for fabricating a transistor according to claim 13, wherein the structuring comprises the removal of a part of the material intended to form the gate covering the gate oxide at the longitudinal end of the nanowire opposite to the substrate, and of another part of the material intended to form the gate covering the gate oxide at the base of the nanowire.

15. Method according to claim 14, wherein it comprises a phase of forming gate, source and drain interconnections, the source and drain interconnections being formed by removal of a part of the gate oxide in areas where the gate material has been removed during the structuring of the gate.

16. Data storage medium that can be read by a calculator, on which is stored a computer program comprising computer program code means for implementing the phases and/or the steps of a method according to claim 8.

17. Computer program comprising a computer program code means suitable for carrying out the phases and/or steps of a method according to claim 8, when the program is executed by a calculator.
